(19) United States
(12) Patent Application Publication
(10) Pub. No.: US 2012/0211056 A1
(43) Pub. Date: Aug. 23, 2012

(54) PHOTOVOLTAIC MODULE

(75) Inventor: Chi-Po CHONG, Hong Kong (HK)

(73) Assignee: Du Pont Apollo Limited, Hong Kong (HK)

(21) Appl. No.: 13/031,252

(22) Filed: Feb. 21, 2011

(51) Int. Cl. H01L 31/048

(52) U.S. Cl. 136/251

(57) ABSTRACT

A photovoltaic module is disclosed, which includes a support, a photovoltaic module, and four brackets for fastening the photovoltaic panel on the support. The ratio of the length distance to the width distance of the s centers of the brackets is same as the ratio of the length to the width of the photovoltaic panel with 3% tolerance.

### BACKGROUND

1. Field of Invention

The present invention relates to a photovoltaic module. More particularly, the present invention relates to brackets of the photovoltaic module.

2. Description of Related Art

Photovoltaic energy is a kind of energy source. Facing the increasing shortage of earth resources, as well as the pollution and safety problems caused by the power driven by a fossil fuel or nuclear energy, photovoltaic energy is a potential alternative energy resource, and many developed countries and large-scale enterprises make efforts in this field to develop the alternative resource.

A photovoltaic module is mostly installed on a roof or the like which is directly irradiated by the sunlight and is not easily shielded by shadows. The traditional method for fixing a photovoltaic module includes using an adhesive to fasten a base onto a roof and then using a bolt to lock the photovoltaic module on the base. However, in this fixing method, the roof needs to be drilled, and even if a waterproof adhesive is coated on the drilling portion, a risk of water leakage still exists.

### SUMMARY

The present invention provides a photovoltaic module, which includes a support, a photovoltaic module, and four brackets for fastening the photovoltaic panel on the support. The photovoltaic panel includes a transparent plate, a back plate, and plural photovoltaic cells sealed between the transparent plate and the back plate. The ratio of the length distance to the width distance of the centers of the brackets is same as the ratio of the length to the width of the photovoltaic panel with 3% tolerance.

The ratio of the length distance of the centers of the brackets to the length of the photovoltaic panel is from 51% to 57%. The ratio of the width distance of the centers of the brackets to the width of the photovoltaic panel is from 51% to 57%. The profile of the bracket is a hat. The bracket includes a middle protrusion and two wings connected to opposite sides of the middle protrusion. The material of the brackets can be steel, titanium, or alloy. The thickness of the bracket can be from 1.0 mm to 1.5 mm. The ratio of the depth of the middle protrusion to the width of the bracket can be from 20% to 26%. The ratio of the width of the wing to the width of the bracket can be from 26% to 32%.

In another aspect, the bracket may further include two ribs connected to opposite sides of the wings respectively, and the ribs are perpendicular to the wings. The material of the brackets can be steel, titanium, or alloy. The thickness of the bracket can be from 0.8 mm to 1.1 mm. The ratio of the depth of the middle protrusion to the width of bracket can be from 18% to 24%. The ratio of the width of the wing to the width of the bracket can be from 22% to 28%.

In another aspect, the photovoltaic module may further include plural adhesive layers for adhering the brackets on the back plate. The photovoltaic module may further include plural screws for screwing the brackets on the support. The ratio of the length of the brackets to the length of the photovoltaic panel can be from 20% to 26%, which is used for 2400 Pa wind loading ability. The ratio of the length of the bracket to the length of the photovoltaic panel can be from 26% to 32%, which is used for 5400 Pa snow loading ability.

The photovoltaic module of the present invention can be a frameless module. The brackets are designed and arranged as a special ratio, therefore the cost and the weight of the brackets disclosed in the above embodiments can be reduced. The brackets can still provide enough supportive strength to withstand strong wind load required in the solar standards.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a sectional diagram of an embodiment of the photovoltaic module of the invention;

FIG. 2 is a bottom view diagram of the photovoltaic module 100 of FIG. 1;

FIG. 3 is a sectional diagram of a first embodiment of the bracket of the invention; and

FIG. 4 is a sectional diagram of a second embodiment of the bracket of the invention.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

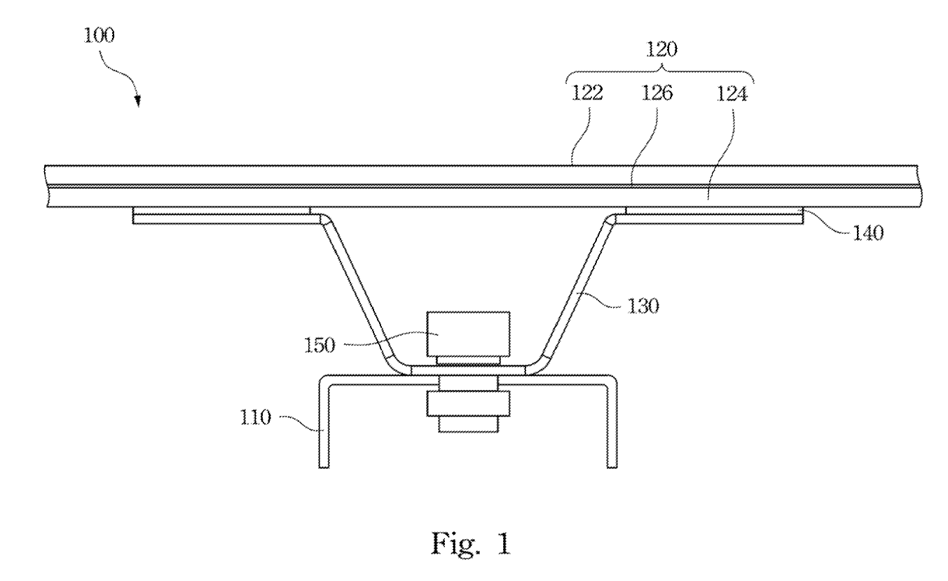

FIG. 1 is a sectional diagram of an embodiment of the photovoltaic module of the invention. The photovoltaic module 100 includes a support 110, a photovoltaic panel 120, and four brackets 130. The support 110 can be fastened on the roof or the like which is directly irradiated by the sunlight and is not easily shielded by shadows. The brackets 130 fasten the photovoltaic panel 120 on the support 110. The photovoltaic panel 120 includes a transparent plate 122, a back plate 124, and plural photovoltaic cells 126 sealed between the transparent plate 122 and the back plate 124. The photovoltaic module 100 further includes plural adhesive layers 140 for adhering the brackets 130 on the back plate 124. The adhesive layers 140 can be adhesive tapes or glue layers. The photovoltaic module 100 further includes plural screws 150 to screw the brackets 130 on the support 110.

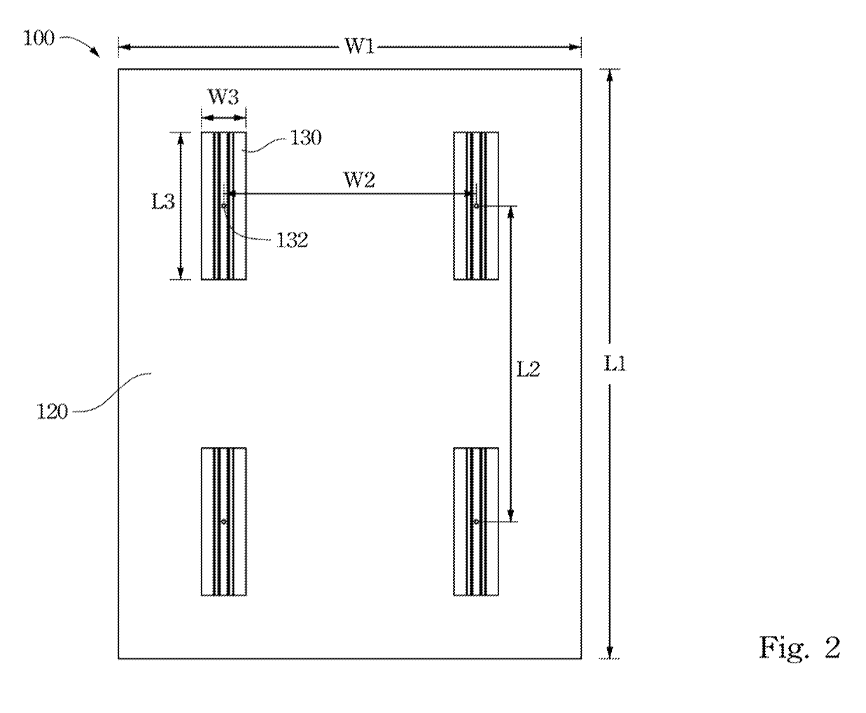

FIG. 2 is a bottom view diagram of the photovoltaic module 100 of FIG. 1. The support 110 in FIG. 1 is omitted in FIG. 2 for better describing. The screw holes of the brackets 130 can be defined at the centers 132 of the brackets 130 or disposed symmetrically to the centers 132. The brackets 130 are arranged related to the shape of the photovoltaic panel 120. The positions of the brackets 130 are defined as the distances between the centers 132 of the brackets 130, wherein “W2” represents to a width distance between the centers 132 of the brackets 130, and “L2” represents to a length distance between the centers 132 of the brackets 130, and “W3” represents the width of the brackets 130, and “L3” represents the length of the brackets 130. “W1” represents the width of the photovoltaic panel 120, and “L1” represents the length of the photovoltaic panel 120. The arrangement of the brackets 130 is constrained by the size of the photovoltaic panel 120. The ratio of the length distance L2 of the centers 132 of the brackets 130 to the width distance W2 of the centers 132 of the brackets 130 is substantially the same as the ratio of the length L1 of the photovoltaic panel 120 to the width W1 of the photovoltaic panel 120 with 3% tolerance; i.e. W2/L2=W1/L1±3%. The middle lines of the centers 132 and the middle lines of the photovoltaic panel 120 are collinear. The ratio of the width distance W2 of the centers 132 of the brackets 130 to the width W1 of the photovoltaic panel 120 is from 51% to 57%, i.e. W2/W1=±3%. The ratio of the length distance L2 of the centers 132 of the brackets 130 to the length L1 of the photovoltaic panel 120 is from 51% to 57%, i.e. L2/L1=54%±3%.

The material of the brackets 130 can be steel, titanium, or alloy. The length of the brackets 130 is constrained to different loading ability. For example, for 2400 Pa of loading ability, the ratio of the length L3 of the brackets 130 to the length L1 of the photovoltaic panel 120 is from 20% to 26%, i.e. L3/L1=23%±3%; for 5400 Pa of snow loading ability, the ratio of the length L3 of the brackets 130 to the length L1 of the photovoltaic panel 120 is from 26% to 32%, i.e. L3/L1=29%±3%.

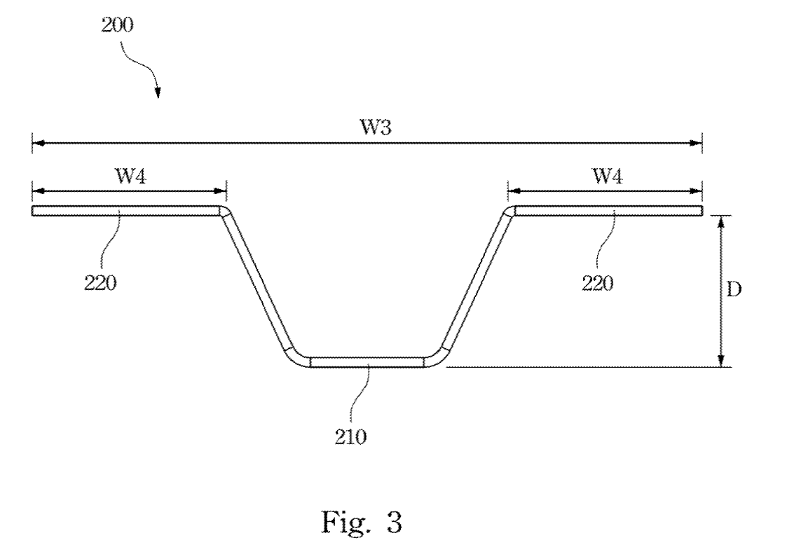

FIG. 3 is a sectional diagram of a first embodiment of the bracket of the invention. The profile of the bracket 200 is a hat shape. The bracket 200 has a middle protrusion 210 and two wings 220 connected to opposite sides of the middle protrusion 210, wherein “W4” represents the width of the wing 220, and “D” represents the depth of the middle protrusion 210, and “W3” represents the width of the bracket 200. The adhesive layers (not shown) are applied on the wings 220. The material of the brackets 200 can be steel, titanium, or alloy. The thickness of the bracket 200 is from 1.0 mm to 1.5 mm. The ratio of the depth D of the middle protrusion 210 to the width W3 of the bracket 200 is from 20% to 26%, i.e. D/W3=23%±3%.The ratio of the width W4 of the wing 220 to the width W3 of the bracket 200 is from 26% to 32%, i.e. W4/W3=29%±3%

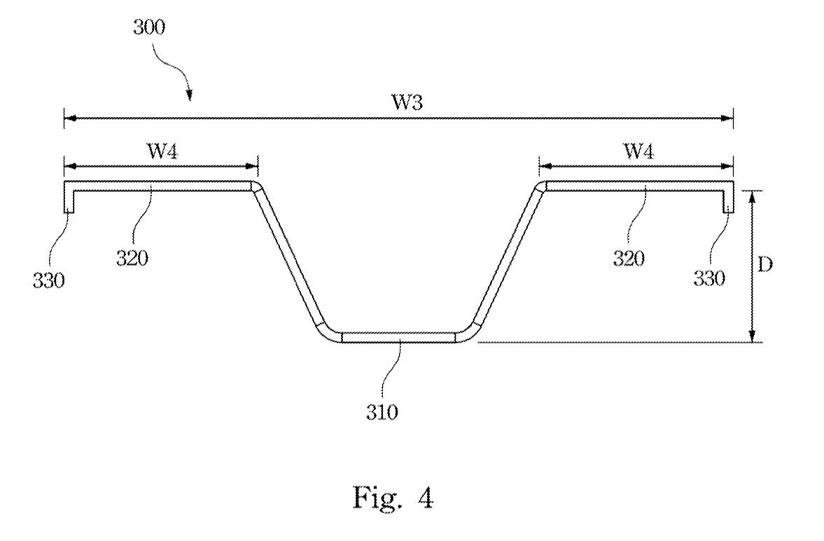

FIG. 4 is a sectional diagram of a second embodiment of the bracket of the invention. The profile of the bracket 300 is a hat. The bracket 300 has a middle protrusion 310, two wings 320 connected to opposite sides of the middle protrusion 310, and two ribs 330 connected to opposites sides of the wings 320 respectively, wherein “W4” represents the width of the wing 320, and “D” represents the depth of the middle protrusion 310, and “W3” represents the width of the bracket 300. The adhesive layers (not shown) are applied on the wings 320. The ribs 330 are perpendicular to the wings 320. The material of the brackets 300 can be steel, titanium, or alloy. The ribs 330 can increase the strength and second moment of area of the bracket 300. The thickness of the bracket 300 is from 0.8 mm to 1.1 mm. The ratio of the depth D of the middle protrusion 310 to the width W3 of the bracket 300 is from 18% to 24%, i.e. D/W3=21%±3%. The ratio of the width W4 of the wing 320 to the width W3 of the bracket 300 is from 22% to 28%, i.e. W4/W3=25%±3%.

The photovoltaic module of the present invention can be a frameless module. The brackets are designed and arranged as a special ratio, therefore the cost and the weight of the brackets disclosed in the above embodiments can be reduced. The brackets can still provide enough supportive strength to withstand strong wind load required in the solar standards.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A photovoltaic module comprising:
a support;
a photovoltaic panel comprising:
a transparent plate;
a back plate; and
a plurality of photovoltaic cells sealed between the transparent plate and the back plate; and
four brackets for fastening the photovoltaic panel on the support, wherein a ratio of a length distance to a width distance of a plurality of centers of the brackets is same as a ratio of a length to a width of the photovoltaic panel with 3% tolerance.

2. The photovoltaic module of claim 1, wherein a ratio of the length distance of the centers of the brackets to the length of the photovoltaic panel is from 51% to 57%.

3. The photovoltaic module of claim 1, wherein a ratio of the width distance of the centers of the brackets to the width of the photovoltaic panel is from 51% to 57%.

4. The photovoltaic module of claim 1, wherein a profile of each of the brackets is a hat shape.

5. The photovoltaic module of claim 1, wherein the each of the brackets comprises a middle protrusion and two wings connected to opposite sides of the middle protrusion.

6. The photovoltaic module of claim 5, wherein a material of the brackets is steel, titanium, or alloy.

7. The photovoltaic module of claim 5, wherein a thickness of each of the brackets is from 1.0 mm to 1.5 mm.

8. The photovoltaic module of claim 5, wherein a ratio of a depth of the middle protrusion to a width of each of the brackets is from 20% to 26%.

9. The photovoltaic module of claim 5, wherein a ratio of a width of each of the wings to a width of each of the brackets is from 26% to 32%.

10. The photovoltaic module of claim 5, wherein each of the brackets further comprises two ribs connected to opposite sides of the wings respectively.

11. The photovoltaic module of claim 10, wherein the ribs are perpendicular to the wings.

12. The photovoltaic module of claim 10, wherein a material of the brackets is steel, titanium, or alloy.

13. The photovoltaic module of claim 12, wherein a thickness of each of the brackets is from 0.8 mm to 1.1 mm.

14. The photovoltaic module of claim 11, wherein a ratio of a depth of the middle protrusion to a width of each of the brackets is from 18% to 24%.

15. The photovoltaic module of claim 11, wherein a ratio of a width of each of the wings to a width of each of the brackets is from 22% to 28%.

16. The photovoltaic module of claim 1, further comprising a plurality of adhesive layers for adhering the brackets on the back plate.

17. The photovoltaic module of claim 1, further comprising a plurality of screws for screwing the brackets on the support.

18. The photovoltaic module of claim 1, wherein a ratio of a length of each of the brackets to the length of the photovoltaic panel is from 20% to 26%.

19. The photovoltaic module of claim 1, wherein a ratio of a length of each of the brackets to the length of the photovoltaic panel is from 26% to 32%.
